(19) United States
(12) Patent Application Publication
(10) Pub. No.: US 2002/0093358 A1
(43) Pub. Date: Jul. 18, 2002

(54) Parallel logic device/circuit tester for testing plural logic devices/circuits and parallel memory chip repairing apparatus

(76) Inventor: Kyung Suk Kang, Yongin-city (KR)

Correspondence Address: F. Chau & Associates, LLP, Suite 501, 1900 Hempstead Turnpike, East Meadow, NY, 11554, US

(21) Appl. No.: 09/992,549

(22) Filed: Nov. 16, 2001

(30) Foreign Application Priority Data
Nov. 18, 2000 (KR) 2000-68757

(51) Int. Cl. G01R 31/26

(52) U.S. Cl. 324/765

(57) ABSTRACT

A parallel logic device/circuit tester is a tester for testing a plurality of devices-under-test (DUTs), in which a proved quality device is made as a reference device and identical signals are input to the reference device and a number of DUTs under the same initial condition, to enable the reference device and the number of DUTs to operate. The parallel logic device/circuit tester includes a main tester unit for generating signals applied to the reference device and the DUTs in order to test the DUTs, and receiving the testing result, to thereby test each DUT, and a bidirectional comparator and detector on which the reference device and the DUTs are loaded, for applying the signals from the main tester unit to the loaded reference device and the loaded DUTs, and comparing the data signals from each of the DUTs with those from the reference device according to the applied signals, to thereby output the compared result as a testing result. As described above, identical signals can be applied to a plurality of DUTs connected in parallel with the reference devices, and the data values of the reference devices and the DUTs are compared by using the bidirectional comparator and detectors, to thereby test a plurality of DUTs on a real-time basis. Also, the output signals from the bidirectional comparator and detector can be used in a repairing apparatus for determining a type of defective cells and repairing the defective cells easily as well as testing DUTs, which makes the present embodiment further effective.

### BACKGROUND OF THE INVENTION

1. Field of the Invention

The present invention relates to a logic device/circuit tester for testing a device and/or a logic circuit and an apparatus for detecting defective cells in each memory chip on a wafer using the same art, and more particularly, to a parallel logic device/circuit tester for testing a plurality of devices-under-test (DUTs) or a plurality of printed circuit boards-under-test (PCBUTs), all at a time. Also, the present invention relates to a memory chip repairing apparatus for detecting defective cells in each memory chip on a wafer to then repair the defective cells in case that a DUT is an integrated circuit (IC) memory chip on a wafer.

2. Description of the Related Art

In general, a final application test for testing logic devices/circuits such as semiconductor chips or semiconductor chip modules, is the final process to eliminate defective products after production of the device or circuit or to guarantee the quality. Accordingly, an efficient and rapid logic device/circuit tester is required in order to inspect a number of logic devices/circuits economically.

FIG. 1 is a block diagram of a conventional logic device/circuit tester for testing a logic device/circuit such as a semiconductor memory chip.

A main tester unit 100 generates address signals, control signals and data signals which are applied to respective devices-under-test (DUTs) 202a, 202b and 202c through address lines A, control lines C and data input/output (I/O) lines D1-D3 which are respectively connected to sockets 201a, 201b and 201c in a handler 200. That is, the main tester unit 100 controls operations of the DUTs 202a, 202b and 202c with control signals, and designates particular positions of the DUTs 202a, 202b and 202c with address signals, at a write mode, to thereby write data on corresponding positions. Also, the main tester unit 100 controls operations of the DUTs 202a, 202b and 202c with control signals, and designates particular positions of the DUTs 202a, 202b and 202c with address signals, at a read mode, to thereby read data from corresponding positions. The main tester unit 100 compares data values read from the respective DUTs 202a, 202b and 202c with predictive results with respect to data signals generated by the main tester unit 100 and applied to the respective DUTs 202a, 202b and 202c, to accordingly detect the defective devices in the respective DUTs 202a, 202b and 202c.

In case of the above-described conventional logic device/circuit tester, the main tester unit 100 receives the data signals from all the DUTs 202a, 202b and 202c and compares the received data signals with the expected result signals, with respect to the data signals which were generated from the main tester unit 100 and applied to the DUTs 202a, 202b and 202c, respectively, by software. Also, the address signals and the control signals can be shared between the main tester unit 100 and a test block 200 where the DUTs 202a, 202b and 202c are located, but the data I/O lines are not shared there between. Accordingly, data I/O lines are required for each DUT in a one-to-one correspondence.

Here, the testing processes for the DUTs 202a, 202b and 202c in the main tester unit 100 are independently performed in each DUT. That is, since transmission of the data signals is performed through respectively different I/O lines, each data signal is independent of other data signals. Thus, the testing processes for each DUT is performed one by one. As a result, as the number of DUTs increases, the whole testing time becomes longer. Further, since the data signal comparison process is performed for each DUT by software in the main tester unit 100, the main tester unit 100 is overloaded during testing as the number of DUTs increases. Accordingly, to increase the tester speed, expensive high-speed processors are required for the stable operation of the tester. Also, the high-speed data I/O lines are expensive, the increase in the number of the expensive data lines burdens the manufacturing cost of the tester for testing a number of DUTs. As described above, the conventional tester is limited costly and physically in proportion to the increase in the number of DUTs.

Also, the results from the conventional tester cannot be used for other purposes, because the results are made by software comparator.

Meanwhile, the conventional testers divide a block into sub-blocks and perform testing sequentially in order to save the loading time taken for loading a DUT into a socket of a handler. However, since the testing time is much longer than the loading time, such a trial is only improvement in the efficiency of a test block.

### SUMMARY OF THE INVENTION

To solve the above problems, it is an object of the present invention to provide a parallel logic device/circuit tester for testing devices-under-test (DUTs) or printed circuit boards-under-test (PCBUTs), all at a time and on a real-time basis with hardware components so as to increase the number of DUTs or PCBUTs.

It is another object of the present invention to provide a parallel logic device/circuit tester for testing a plurality of devices-under-test (DUTs) on a printed circuit board (PCB), on a real-time basis.

It is still another object of the present invention to provide a memory chip repairing apparatus for detecting the exact location of defective cells in a corresponding DUT to thereby repair the defective cell.

To accomplish the above objects of the present invention, there is provided a parallel logic device/circuit tester for testing a plurality of devices-under-test (DUTs), all at a time and on a real-time basis, characterized in that: a reference device is loaded in parallel with a number of DUTs; identical signals are applied to the inputs of the reference device and the number of DUTs under the same initial conditions; and data signals output from the reference device are compared with those from each DUT by using hardware components.

### BRIEF DESCRIPTION OF THE DRAWINGS

The above objects and other advantages of the present invention will become more apparent by describing the preferred embodiment thereof in more detail with reference to the accompanying drawings in which:

FIG. 1 is a block diagram of a conventional logic integrated circuit (IC) tester for testing a logic circuit such as a semiconductor chip;

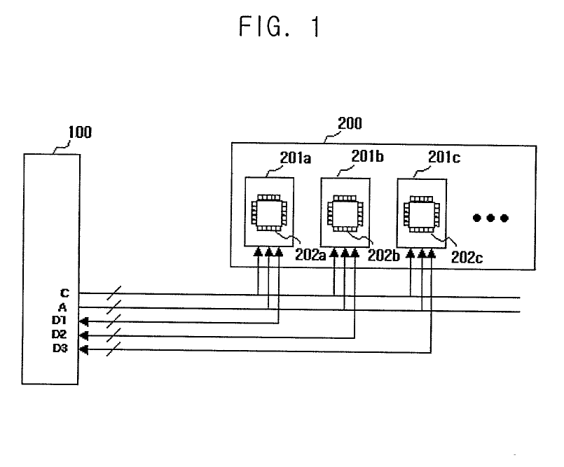

FIG. 2 is a block diagram of a logic device/circuit tester according to a first embodiment of the present invention;

FIG. 3 is a block diagram of a bidirectional comparator and detector of the FIG. 2 tester;

FIGS. 4A and 4B are timing diagrams between data signals from a reference device and those from a DUT in the bidirectional comparator and detectors;

FIG. 5 is a block diagram of a logic device/circuit tester according to a second embodiment of the present invention;

FIG. 6 is a block diagram of a memory chip repairing apparatus according to the present invention; and

FIG. 7 shows an operation of testing memory chips on a wafer by using a wafer probe header on which a wafer tester probe block is mounted.

### DETAILED DESCRIPTION OF THE INVENTION

Preferred embodiments of the present invention will be described with reference to the accompanying drawings.

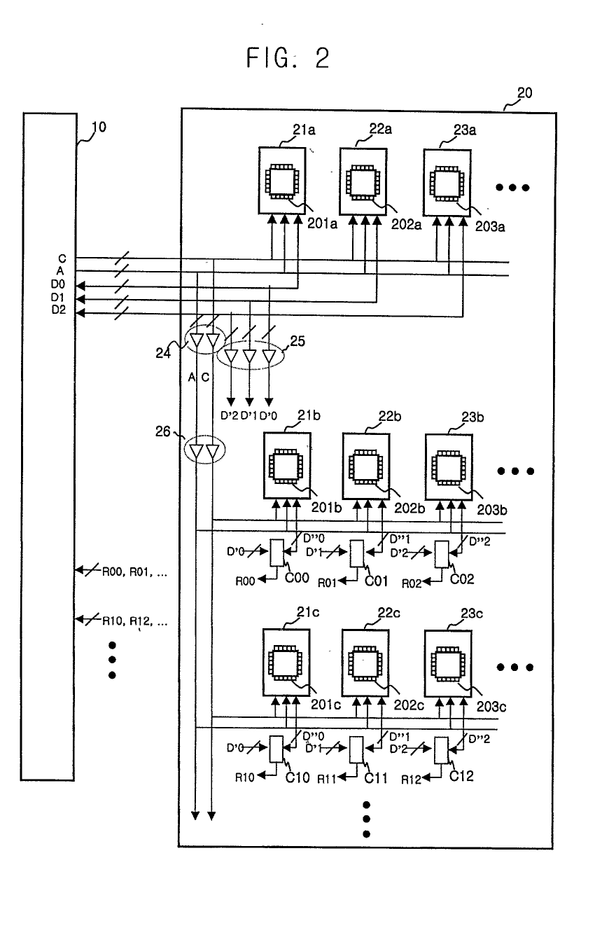

In FIG. 2 showing a block diagram of a logic circuit tester according to a first embodiment of the present invention, a main tester unit 10 generates address signals, control signals and data signals in order to test devices-under-test (DUTs) such as digital integrated circuits (ICs) or digital circuit modules, and then outputs the generated signals through address lines A, control lines C and data input/output (I/O) lines (D0, D1, . . . ). Also, the main tester unit 10 receives comparison signals (R00, RO1, . . . , R10, R11, . . . , . . . ) from a first test block 20 to be described later, and detects the defective of each DUT, to thereby locate defective cells in the DUT that has been determined as the defective DUT. The comparison signals are obtained by comparing a data signal from one or those from a plurality of reference devices (201a, 202a, 203a, ) with those from DUTs (201b, 201c, . . . , 202b, 202c, . . . , 203b, 203c . . . , . . . ) which are connected in parallel with respect to each reference device in one column or plural columns, respectively, which will be described later in more detail.

A number of sockets (21a, 21b, 21c, . . . , 22a, 22b, 22c, . . . , 23a, 23b, 23c . . . . . . . . ) where the reference devices (201a, 202a, 203a, . . . ) and the DUTs (201b, 201c, 202b, 202c, . . . , 203b, 203c . . . , . . . ) are respectively loaded and electrically connected are installed in the first test block 20. Each of the sockets (21a, 22a, 23a, . . . ) (referred to as reference sockets) where the reference devices (201a, 202a, 203a, . . . ) are loaded is installed in parallel with the sockets (21b, 21c, . . . , 22b, 22c, . . . , 23b, 23c. . . , . . . ) (referred to as DUT sockets) where the DUTs (201b, 201c, . . . , 202b, 202c, . . . , 203b, 203c. . . , . . . ) are respectively loaded. That is, the reference socket 21a and the DUT sockets (21b, 21c, . . . ) form a parallel set, the reference socket 22a and the DUT sockets (22b, 22c, . . . ) form another parallel set, and the reference socket 23a and the DUT sockets (23b, 23c, . . . ) form still another parallel set. As shown in FIG. 2, a plurality of the parallel sets form a single test block, or can be independently configured so that they are separated from or combined with each other. Bidirectional comparator and detectors (C00, C10, . . . , C01, C11, . . . , C02, C12, . . . , . . . ) to be described later are installed in correspondence to the respective DUT sockets (21b, 21c, . . . , 22b, 22c, . . . , 23b, 23c, . . . ).

A circuitry pattern of the test block 20 is configured so that identical signals are applied to a certain reference socket 21a and a plurality of DUT sockets (21b, 21c, . . . ) installed in parallel with the certain reference socket 21a, that is, each parallel set. Here, the identical signals does not only mean that they have the same data values as those of the signals output from the identical data terminals in the main tester unit 10. That is, a data signal is simultaneously applied to the parallel sets (21a, 21b, 21c, . . . ), through a data line D′0 branched from a data line D0 connected between the main tester unit 10 and the reference socket 21a. Other identical signals are applied to each of the other parallel sets (22a, 22b, 22c, . . . , 23a, 23b, 23c . . . , . . . ), through a data line D′1 branched from a data line D1 connected between the main tester unit 10 and the reference socket 22a., and through a data line D′2 branched from a data line D2 connected between the main tester unit 10 and the reference socket 23a, respectively.

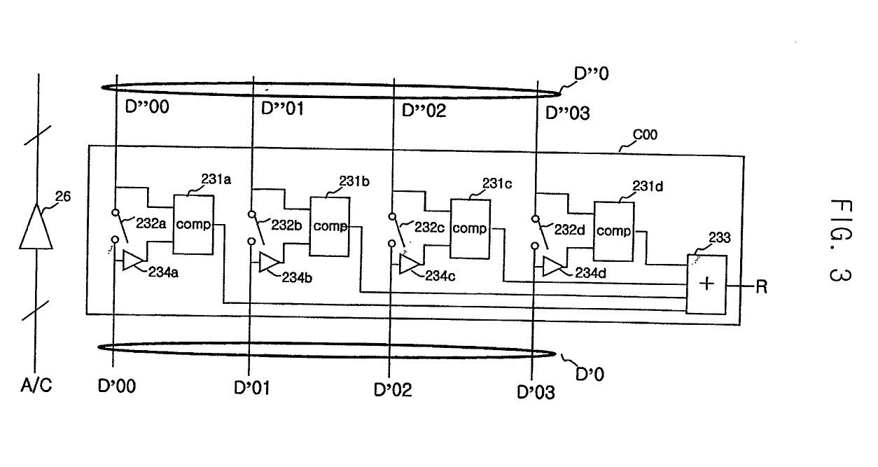

Each of the bidirectional comparator and detectors (C00, C10,. . . C01, C11, . . . , C02, C12, . . . , . . . ) compares the data signal output from each of the reference devices (201a, 202a, 203a, . . . ) with that output from each of the DUTs (201b, 201c, . . . , 202b, 202c, . . . , 203b, 203c, . . . , . . . ), and then outputs the compared result as a one-bit signal for each DUT. FIG. 3 is a block diagram of a bidirectional comparator and detector C00. The other bidirectional comparator and detectors (C01, C02, . . . , C10, C11, . . . ) in the present invention have the same structure and function as that of FIG. 3. Thus, the present invention will be described with respect to the one bi-directional comparator and detector C00 and the reference device 201a and the DUT 201b which correspond to the one bidirectional comparator and detector C00.

The bidirectional comparator and detector C00 includes switches 232a-232d, comparators 231a-231d, and a logic gate 233, which performs a number of logical comparison and logical sum operation, as many as the number of bits in the data lines (four bits in an embodiment of the present invention). The switches 232a-232d are turned on at a write mode so that data signals are applied from the main tester unit 10 to the DUT 201b, and are turned off at a read mode so that data signals from the reference device 201a and those from the DUT 201b are applied to the comparators 231a-231d, respectively. The comparators 231a-231d compare the two input data signals. The logic gate 233 performs a logical sum operation of the data signals output from the comparators 231a-231d and outputs a one-bit signal R00 to the main tester unit 10. Here, the switches 232a-232d cause delays in the data transmission. Accordingly, compensation for the delay in the data transmission is required. A second delay to be described later plays a role of the delay compensation.

Bus drivers 24 are to prevent processing time delay due to the increase in the load (mainly capacitive load) on each signal line from the main tester unit 10, in which the processing time delay occurs during parallel testing, and reduce capacitance with respect to each signal line due to the connected DUTs (201b, 201c, . . . , 202b, 202c, 203b, 203c. . . , . . . ). That is, the bus drivers 24 prevent the processing time delay of each signal line of the main tester unit 10, to thereby connect each DUT signal line in parallel with the reference devices. A buffer or a flip-flop (F/F) can be used as the bus drivers 24. If there are no bus drivers 24, the total capacitance load value of the signal lines from the main tester unit 10 increases as the number of DUTs increases, and thus the driving capability of the system becomes lower. However, control signals and address signals will be delayed for a certain amount of time by the bus drivers 24. Accordingly, a delay 25 is installed on the data lines (D′0, D′1, . . . ), respectively, to thus compensate for the delay caused by the bus drivers 24. The delay 25 is made of the same device as that of the bus drivers 24. The bus drivers 24 and 25 are used together, and their functions can be changed each other.

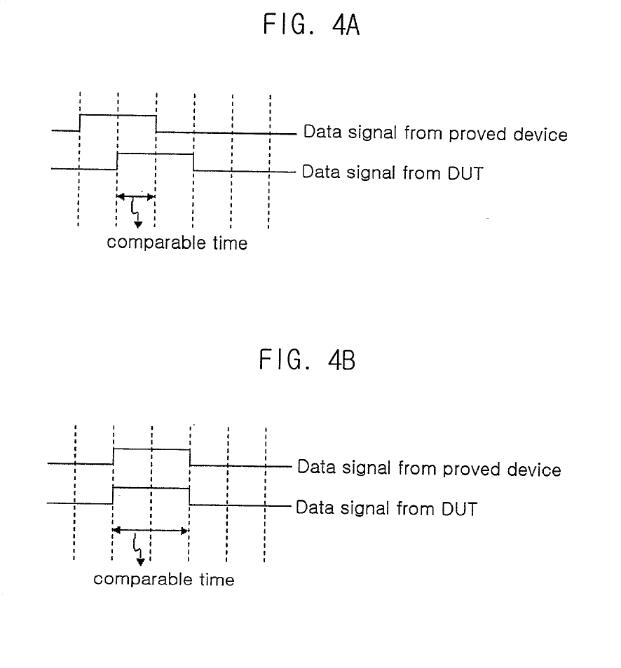

A delay 26 is installed on the address line A and the control line C, respectively, in order to compensate for the delay of the data signals due to the switches 232a-232d at a write mode, and to delay the address signals and the control signals as much as an amount of delayed time of the data signal. By the way, the data signal from the DUT 201b is delayed at a read mode due to a use of the delay 26, and is not synchronized with the data signal from the reference device 201a. As a result, as shown in FIG. 4A, a comparable time of the two data signals is shortened. In order to solve the above problem, the data signal from the reference device 201a which is applied to the respective comparators 231a-231d need to be delayed as much as the delay time of the delay 26. Additional delays 234a-234d perform such a function. The delay 26 and the delays 234a-234d can be omitted in a low speed tester, and can be implemented as other means through clock adjustment by use of a phase locked loop (PLL).

The operation of the logic circuit tester according to the present invention will be described in a whole.

Since the functions of reference devices, DUTs and bidirectional comparator and detectors (BCDs) are repeated in parallel, a single parallel set of a plurality of parallel sets (201a, 201b, 201c, . . . ), in particular, only the operations of the DUT 201b and the reference device 201a, the bidirectional comparator and detector C00 and the corresponding data lines D0, D′0 and D″0 corresponding to the DUT 201b will be described below.

In the event that control signals are at a write mode, data signals generated in the main tester unit 10 are applied to a reference device 201 a loaded in a reference socket 21a through data lines D0, and simultaneously applied to DUTs (201b, 201c, . . . ) connected in parallel with the reference device 201a, to then be recorded on a position designated by an address signal. Then, in the event that control signals are at a read mode, the switches 232a-232d are turned off, and thus data signals from the reference device 201a and the DUT 201b are applied to the bidirectional comparator and detector C00 through data lines D′0 and D″0, respectively. The two data signals applied to the bidirectional comparator and detector C00 are compared on a bit-by-bit basis in the comparators 231a-231d. The compared result is output to a logic device 233. The logic gate 233 performs a logical sum operation of the signals output from the comparators 231a-231d and outputs a one-bit signal R00 to the main tester unit 10, The main tester unit 10 uses the received signal R00 to test the DUT 201b. In particular, the main tester unit 10 can determine the exact defected cell address when the DUT 201b is determined as a defected device. By the way, the data signals applied to the DUT 201b at a write mode are delayed for a certain amount of time due to the switches 232a-232d. In order to solve the above delay problem, the address signals and the control signals which are applied to the DUT 201b should be delayed as much as an amount of the time delayed by the switches 232a-232d. Thus, as shown in FIG. 2, delays 26 are installed on the address lines A and the control lines C, which are connected to the DUT 201b. A buffered driver is used as the delay. However, the delay 26 delays the control signals and the address signals which are applied to the DUT 201b even at a read mode and the data signals from the DUT 201b are delayed to then be applied to the bidirectional comparator and detector C00. For this reason, as shown in FIG. 4A, a comparable time between the data signals from the reference device 201a and those from the DUT 201b is shortened. In order to solve the above problem, the data signals applied from the reference device 201a to the bidirectional comparator and detector C00 at a read mode should be delayed as much as a delay time of the delay 26. For this purpose, as shown in FIG. 3, additional delays 234a-234d which are the same as the delays 26 are installed on the terminals where the data signals are input from the reference device 201a between the two input terminals of the respective comparators 231a-231d at a read mode. That is, the delays 234a-234d are not used at a write mode but delay the data signals only at a read mode. FIG. 4B illustrates that a comparable time is lengthened by synchronizing the two data signals by use of the delays 234a-234d.

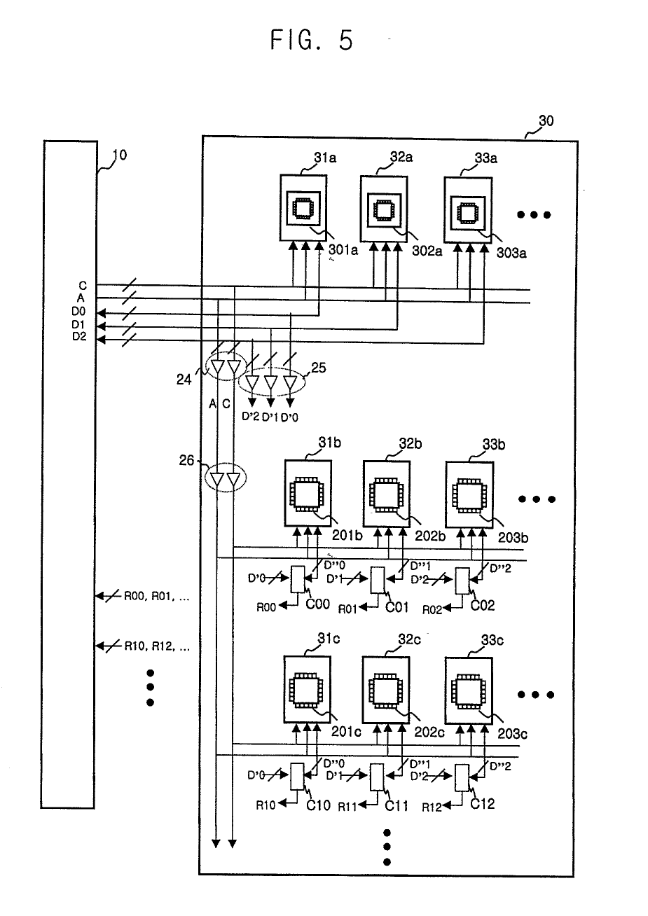

FIG. 5 is a block diagram of a logic circuit tester according to a second embodiment of the present invention.

A certain DUT needs an application test. It is because the DUT mounted on a certain printed circuit board (PCB) may not operate well although the DUT operates well alone. The FIG. 5 tester is used to test DUTs mounted on a certain PCB.

In a test block 30, functions of reference sockets and DUT sockets are different from the reference sockets (21a, 22a, 23a, . . . ) and the DUT sockets (21b, 21c, . . . , 22b, 22c, . . . , 23b, 23c. . . , . . . ) of the test block 20. That is, instead of the reference sockets (21a, 22a, 23a, . . . ) of FIG. 2, PCB sockets (31a, 32a, 33a, . . . ) are installed on which proved reference PCBs (301a, 302a, 303a, . . . ) are loaded. Also, instead of the DUT sockets (21b, 21c, . . . , 22b, 22c, . . . , 23b, 23c. . . , . . . ) of FIG. 2, DUT test boards (31b, 31c, . . . , 32b, 32c, . . . , 33b, 33c. . . . ) are installed in parallel with the PCB sockets (31a, 32a, 33a, . . . ). The DUT test circuits (31b, 31c, . . . , 32b, 32c, . . . , 33b, 33c. . . , . . . ) have the same circuitry configuration as those of the reference PCBs if the DUTs (201b, 201c, . . . , 202b, 202c, . . . , 203b, 203c. . . , . . . ) are loaded, respectively. Data from the reference PCBs (301a, 302a, 303a, . . . ) is compared with those from the DUT test circuits (31b, 31c, 32b, 32c, . . . , 33b, 33c. . . ) on which the DUTs (201b, 201c, . . . , 202b, 202c, . . . , 203b, 203c. . . , . . . ) are loaded, and then the operation of DUTs in particular PCB can be tested, without assembling the DUTs (201b, 201c, . . . , 202b, 202c, . . . , 203b, 203c. . . . , . . . ) on the PCB.

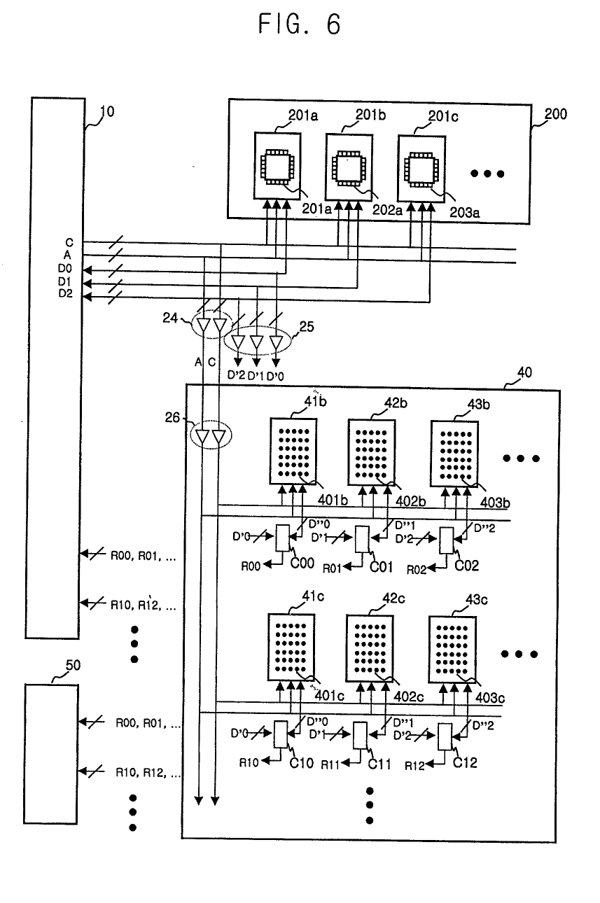

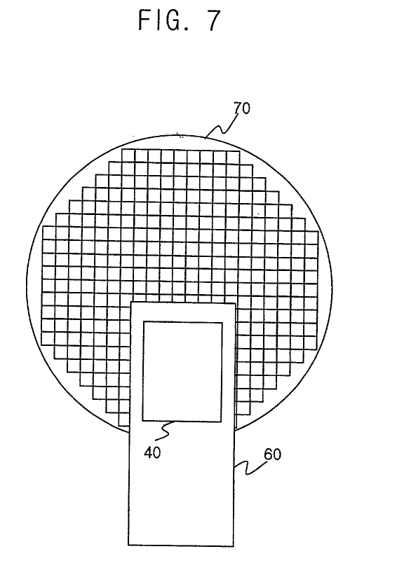

FIG. 6 is a block diagram of a repairing apparatus for finding defective cell of each memory chip on a wafer in order to repair the defective cell, by using signals (R00, R01, R02, . . . , R10, R11, R12, . . . , . . . ) output from the respective bidirectional comparator and detectors (C00, C01, C02, . . . , C10, C11, C12, . . . , . . . ) of FIG. 2 in case that a DUT is a memory chip on a wafer. FIG. 7 shows an operation of testing a memory chip on a wafer by using a wafer probe header, in a simplified form.

A wafer tester probe block 40 includes one or more probe sets (41b, 41c, . . . , 42b, 42c, . . . , 43b, 43c. . . , . . . ) for testing a plurality of memory chips on a wafer 70, and bidirectional comparator and detectors (C00, C10, . . . , C01, C11, . . . , C02, C12 . . . , . . . ) in correspondence to the plurality of probe sets (41b, 41c, . . . , 42b, 42c, . . . , 43b, 43c. . . , . . . ) on a one-to-one basis. A wafer tester probe block 40 is mounted on a wafer probe header 60. Here, as shown in FIGS. 2 and 5, the plurality of probe sets (41b, 41c, . . . , 42b, 42c, . . . , 43b, 43c. . . ) are connected in parallel with the reference sockets (201a, 201b, 201c, . . . ) on which the reference devices (201a, 202a, 203a, . . . ) are loaded. That is, if probes (401b, 401c, . . . , 402b, 402c, . . . , 403b, 403c. . . , . . . ) are electrically connected to the terminals of the respective memory chips on the wafer during testing the wafer, the respective probe sets(41b, 41c, . . . , 42b, 42c, . . . , 43b, 43c. . . ) perform the same functions as those of the plurality of sockets on which the DUTs are loaded in the test block 20 of FIG. 2. Also, if the sockets (201a, 201b, 201c, . . . ) on which the reference devices are loaded are replaced by the PCB sockets on which the excellent memory ICs are loaded, and the probe sets (41b, 41c, . . . , 42b, 42c, . . . , 43b, 43c. . . , . . .) have the same circuit configuration as those of the reference PCBs, it can be tested normal operation of a memory chip on a certain PCB.

A repairing apparatus 50 repairs defective cells by replacing the defective cell in the memory chip by redundancy cells in the corresponding memory chip. The repairing of the defective cell is the same as that of the conventional repairing apparatus. However, the present invention receives the output signals (R00, R01, R02, . . . , R10, R11, R12 . . ., . . . ) from the bidirectional comparator and detectors (C00, C10, . . . , C01, C11, . . ., C02, C12 . . ., . . . ) to then locate and repair the defective cells easily.

FIG. 6 shows an embodiment including a plurality of probe sets which test and repair a plurality of memory chips simultaneously. However, it is apparent that a single probe set can be used.

Also, the test result signals (R00, R01, R02, . . . , R10, R11, R12, . . . , . . . ) are input to a measuring apparatus (for example, a waveform analyzer) such as an oscilloscope or a logic analyzer, as a trigger source, to thereby determine the defective type with respect to the defective cell. In addition to the case that data values are simply compared in a memory chip to test the IC memory, a defective type as well as a defect occurrence frequency need to be determined in the event that an ASIC is tested. Thus, it is very useful that the output data signals from the bidirectional comparator and detectors (C00, C10, . . ., C01, C11 . . . , C02, C12 . . . , . . . ) are analyzed with a measuring apparatus, to thereby determine a type of a defective cell.

As described above, the present invention is configured so that identical signals can be applied to a plurality of DUTs connected in parallel with reference devices, and the data values of the reference devices and the DUTs are compared by using the bidirectional comparator and detectors, to thereby test a plurality of DUTs on a real-time basis. Also, the output signal from the bidirectional comparator and detector can be used in a repairing apparatus for determining a type of a defective cell and repairing the defective cell easily as well as testing DUTs, which makes the present invention further effective.

What is claimed is:

1. A parallel logic device/circuit tester for testing a plurality of devices-under-test (DUTs),
characterized in that:
a reference device is loaded in parallel with a number of DUTs;
identical signals are applied to the inputs of the reference device and the number of DUTs under the same initial conditions; and
data signals output from the reference device are compared with those from each DUT by using hardware components.

2. The parallel logic device/circuit tester of claim 1, wherein said tester comprises:
a main tester unit for generating signals applied to the reference device and a plurality of DUTs, and receiving comparison signals by comparing the data signals from the reference device with those from the plurality of DUTs, in order to test the DUTs; and
at least one test block in which the reference device and the plurality of DUTs are electrically loaded in parallel with each other, including the hardware components for comparing the data signals output from the reference device with those from each DUT according to the signal applied from the main tester unit, to thereby output the test result to the main tester unit.

3. The parallel logic device/circuit tester of claim 2, wherein said main tester unit locates defective cells in the DUT determined as the defective cell, and outputs an address of the defective cell.

4. The parallel logic device/circuit tester of claim 2, wherein said test block branches off data signals applied from the main tester unit, and applies the same data signals to the reference device and the plurality of DUTs which are loaded in the corresponding test block.

5. The parallel logic device/circuit tester of claim 2, wherein said test block comprises:
a plurality of sockets on which the reference device and the plurality of DUTs are loaded and electrically connected with each other;
bidirectional comparator and detectors which are installed in correspondence to the respective sockets on which the DUTs are loaded, for comparing the data signals output from the corresponding DUT with those from the reference device, to then output the test result; and
a circuitry pattern for applying the data signals from the main tester unit to the reference device and the plurality of DUTs, simultaneously and applying the output signals from the bidirectional comparator and detectors to the main tester unit.

6. The parallel logic device/circuit tester of claim 5, further comprising a measuring apparatus for outputting a waveform with respect to a defective cell in the defective DUT by using of the output signals from the bidirectional comparator and detectors as a trigger signal.

7. The parallel logic device/circuit tester of claim 2, wherein said test block further comprises: bus drivers for compensating for processing time delay due to the increase in load of each signal line in the main tester unit, and for reducing capacitance with respect to each signal line due to the connected DUTs.

8. The parallel logic device/circuit tester of claim 7, wherein said bus drivers are of a buffer, respectively.

9. The parallel logic device/circuit tester of claim 7, wherein said bus drivers are of a flip-flop, respectively.

10. The parallel logic device/circuit tester of claim 5, wherein said bidirectional comparator and detector comprises:
a switching portion for turning on the data lines connected to each DUT at a write mode and turning off the same at a read mode;
comparators for comparing the data signals from the reference device with those from the DUTs at a read mode, and outputting the comparison signals; and
a logic gate for performing a logical sum operation of the output signals from said comparators, and outputting the operated result.

11. The parallel logic device/circuit tester of claim 10, further comprising:
a first delay means for delaying the control signals and the address signals applied to the DUT as much as an amount of time delayed by the switching portion, in order to compensate for a delay time of the data signals applied to the DUT due to the switching portion; and
a second delay means for delaying the data signals output from the reference device and applied to the comparator as much as the second delay time, in order to compensate for a delay time of the data signals output from the DUT and applied to the comparator due to the first delay means at a read mode.

12. The parallel logic device/circuit tester of claim 11, wherein said first and second delay means are of a buffered driver, respectively.

13. A tester for testing a device-under-test (DUT), when a proved PCB (printed circuit board) is used as a reference PCB and a DUT are loaded on a PCB having the same circuitry configurations as that of the reference PCB, the tester comprising:
a PCB socket on which the reference PCB is loaded;
a plurality of DUT test circuits on which the DUT is loaded, connected in parallel with the PCB socket, and having the same circuitry configurations as those of the reference PCB if the DUT is loaded thereon;
bidirectional comparator and detectors installed on the DUT test board on a oneto-one correspondence, for comparing the data signals from the PCB socket with those of the each DUT test circuits on which the DUT is loaded and outputting the comparison signals;
a main tester unit for generating signals applied to the reference PCB and the DUT test board in order to test the DUT, receiving the comparison signals from the bidirectional comparator and detector, and testing normal operation of DUTs when the DUT is assembled on the PCB; and
a circuitry pattern for applying the data signal from the main tester unit to the reference PCB and a plurality of test circuits simultaneously, and applying the output signals from the bidirectional comparator and detectors to the main tester unit.

14. A memory chip repairing apparatus for testing and repairing a memory chip with comparing data of the memory chip on the reference device and the wafer, and testing the memory chip when a proved memory chip is used as a reference device and repairing the defective cell, the memory chip repairing apparatus comprising:
a main tester unit for generating signals applied to the reference device and a plurality of memory chips in order to test the memory chips, receiving the comparison signals between the reference device and a plurality of memory chips, and testing the memory chips;
a reference device block on which at least said one reference device is loaded; and
a wafer test probe block mounted on a wafer probe head, including at least one probe set electrically connected to each memory chip, transmitting the signals from the main tester unit to said each memory chip, comparing the data signals from the reference device with those of the memory chip, and outputting the comparison signals.

15. The memory chip repairing apparatus of claim 14, further comprising a repairing portion for receiving the comparison signals from the wafer test probe block and replacing defective cell in the defective memory chip by a redundancy cell in the defective memory chip to thereby repair the defective memory chip.

16. The memory chip repairing apparatus of claim 14, wherein said wafer test probe block comprises:
at least one probe set electrically connected in parallel with the reference device, and electrically connected with each of the memory chips, to thereby transmit the signals from said main tester unit to said each memory chip and output the data signals from said each memory chip;
bidirectional comparator and detectors installed on the probe set on a one-to-one correspondence, for comparing the data signals from the corresponding memory chip with those of the reference device connected in parallel with the memory chip and outputting the test result; and
a circuitry pattern for applying the data signals from the main tester unit to the reference device and the probe set connected in parallel with the reference device, simultaneously and applying the output signals from the bidirectional comparator and detector externally.
